(19) United States
(12) Patent Application Publication
(10) Pub. No.: US 2008/0188025 A1
(43) Pub. Date: Aug. 7, 2008

(54) Semiconductor device manufacturing method

(75) Inventor: Makiko Nakamura, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/000,809

(22) Filed: Dec. 18, 2007

(30) Foreign Application Priority Data
Feb. 5, 2007 (JP) 2007026045

(51) Int. Cl. H01L 21/56

(52) U.S. Cl. 438/51; 257/E21.502

(57) ABSTRACT

A movable structural body formed over a semiconductor substrate is covered with a sacrifice film. The sacrifice film is covered with a silicon oxide film. Further, through holes are defined in the silicon oxide film. The sacrifice film is removed through the through holes to form space between the movable structural body and the silicon oxide film. Aluminum or an aluminum alloy high in flowability is deposited over the silicon oxide film by a sputtering method to seal the through holes.

### BACKGROUND OF THE INVENTION

The present invention relates to a method for manufacturing a semiconductor device such as a MEMS (Micro Electric Mechanical System) device or the like wherein a mechanical element part such as a vibrator, a sensor, an actuator, an electronic circuit, and the like are integrated on one substrate.

As a conventional semiconductor device manufacturing method, there is known one in which a sacrifice film deposited around a vibrator corresponding to a structural body (mechanical element part) disposed on a substrate is removed and thereafter a portion above the vibrator is sealed by depositing an oxide film by CVD (Chemical Vapor Deposition) (refer to, for example, a patent document 1 (Specification of U.S. Pat. No. 5,188,983)).

The above conventional technique is however accompanied by the problem that since a high temperature of 550° C. or higher is used where the upper portion is sealed by CVD, a structure prior to such a sealing step must be set to such one as being capable of resisting the high temperature, and hence one low in melting point, such as aluminum cannot be used.

A problem also arises in that while it is desirable to bring a sealed hollow portion into high vacuum, it is difficult to cause the hollow portion to reach high vacuum where CVD is used.

Further, a problem arises in that there is a possibility that since a film is grown even around a vibrator lying inside a hollow where the upper portion is sealed by CVD (patent document 1: FIG. 14), the characteristic of the vibrator will vary.

The present invention aims to solve such problems.

### SUMMARY OF THE INVENTION

With the foregoing in view, an object of the present invention is therefore to provide a semiconductor device manufacturing method which makes it possible to use a structural body formed of a material low in melting point and bring space in which the structural body is sealed into high vacuum and which avoids a sealing member from being deposited on the structural body.

According to one aspect of the present invention, for attaining the above object, there is provided a semiconductor device manufacturing method comprising the steps of covering a movable structural body formed over a semiconductor substrate with a sacrifice film, covering the sacrifice film with a first sealing member, forming through holes in the first sealing member, removing the sacrifice film through the through holes and forming space between the structural body and the first sealing member, and depositing a second sealing member high in flowability over the first sealing member by a sputtering method thereby to seal the through holes.

The present invention constructed in this way obtains advantageous effects in that a sealed structural body is not subjected to a high temperature and a structural body formed of a material low in melting point can be used.

An advantageous effect is obtained in that sealed space can be brought into high vacuum.

Further, advantageous effects are obtained in that no sealing member is deposited on the structural body and the characteristic of the structural body is prevented from varying.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a sectional view of a semiconductor device in which a structural body according to an embodiment is sealed;

FIG. 2A to FIG. 2I show sectional views set every step in a semiconductor device manufacturing method according to an embodiment;

FIG. 3A and FIG. 3B are plan views of the semiconductor device according to the embodiment; and

FIG. 4A to FIG. 4D are sectional views of a through hole sealed in an embodiment.

### DETAILED DESCRIPTION OF THE PREFERRED EMBODIMENTS

A preferred embodiment of a semiconductor device manufacturing method according to the present invention will hereinafter be described with reference to the accompanying drawings.

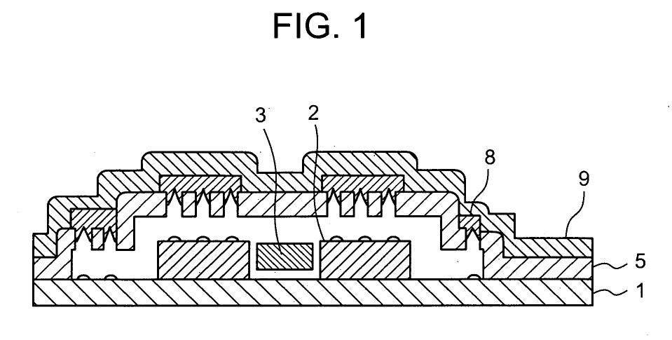

FIG. 1 is a sectional view of a semiconductor device wherein a structural body according to an embodiment is sealed.

In FIG. 1, reference numeral 1 indicates a semiconductor substrate, which has unillustrated transistors and multilayered wirings.

Reference numerals 2 indicate electrodes, which are formed on the semiconductor substrate 1 by polysilicon, silicon germanium (SiGe) or the like.

Reference numeral 3 indicates a movable structural body, which is formed on the semiconductor substrate 1 by a cantilever beam structure or a double supported beam structure or the like. The movable structural body 3 is of a vibrator and has a height that ranges from about 1 μm to 5 μm.

Incidentally, the shapes or the like of the electrodes 2 and the movable structural body 3 are not limited in particular in the present invention. The shapes thereof may be any shape or the like, i.e., they can be selected suitably.

Reference numeral 5 indicates a first sealing or encapsulating member, reference numeral 7 indicates a TiN (nitride titanium) layer, and reference numeral 8 indicates a second sealing or encapsulating member, all of which are formed so as to cover the electrodes 2 and the movable structural body 3 formed on the semiconductor substrate 1 and seal the electrodes 2 and the movable structural body 3 into space formed between the same and the semiconductor substrate 1.

The first sealing member 5 has through holes provided to form space between the first sealing member 5 and the semiconductor substrate 1. The second sealing member 8 blocks or closes the through holes and seals the electrodes 2 and the movable structural body 3 into the space defined between the second sealing member 8 and the semiconductor substrate 1.

The first sealing member 5 is constituted of, for example, a silicon oxide film. The second sealing member 8 is made up of a material high in flow property (flowability), e.g., aluminum or an aluminium alloy.

Reference numeral 9 indicates a silicon nitride film, which is deposited or grown so as to cover the first sealing member 5 and the second sealing member 8 that form space between the same and the semiconductor substrate 1.

Thus, in the semiconductor device according to the present invention, the space, i.e., hollow region is defined between the first sealing member 5 and the second sealing member 8 both formed so as to cover the electrodes 2 and the movable structural body 3 formed over the semiconductor substrate 1, and the semiconductor substrate 1.

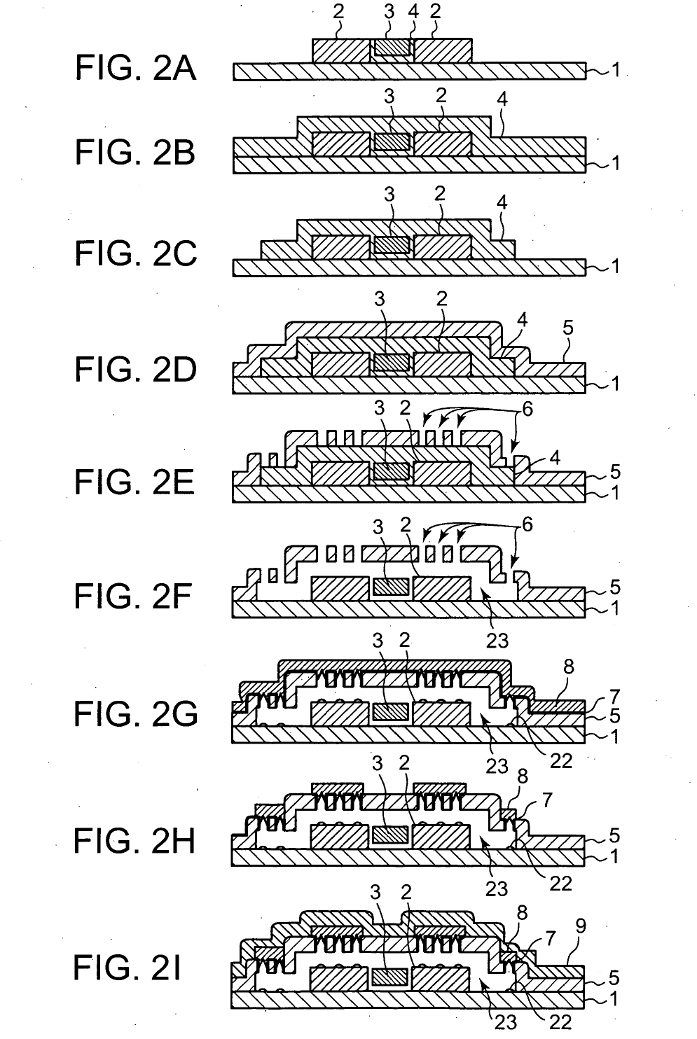

A semiconductor device manufacturing method will next be explained based on sectional views FIG. 2A through FIG. 2I set every step in the semiconductor device manufacturing method according to the embodiment.

Assume that electrodes 2 and a structural body 3 movable with a cantilever beam structure or a double supported beam structure are formed on a semiconductor substrate 1 as shown in FIG. 2A.

Assume here that, for example, a germanium (Ge) layer is used as a sacrifice layer 4 to form the movable structural body 3 of beam structure.

Next, as shown in FIG. 2B, a sacrifice film 4 such as a germanium (Ge) layer or the like is deposited so as to cover the electrodes 2 and the movable structural body 3 formed on the semiconductor substrate 1 by an LP-CVD (Low Pressure Chemical Vapor Deposition) method or the like. The sacrifice film 4 is deposited to about 1.0 μm, for example.

When the sacrifice film 4 is deposited, part of the sacrifice film 4 is processed by photolithography and etching as shown in FIG. 2C to leave an area or region to be sealed with vacuum and remove the sacrifice film 4 in other regions.

When the sacrifice film 4 lying in the region to be sealed with vacuum is formed so as to be left behind, a first sealing member 5 formed of a silicon oxide film or the like is deposited by a plasma CVD method or the like so as to cover the sacrifice film 4. The first sealing member 5 is deposited to a thickness of about 0.7 μm, for example.

When the first sealing member 5 is deposited, through holes 6 which are holes that penetrate the first sealing member 5 and are used to remove the sacrifice layer 4, are formed by photolithography and etching as shown in FIG. 2E. Assume that the diameter of each of the through holes 6 is formed so as to come to about 0.5 μm, for example.

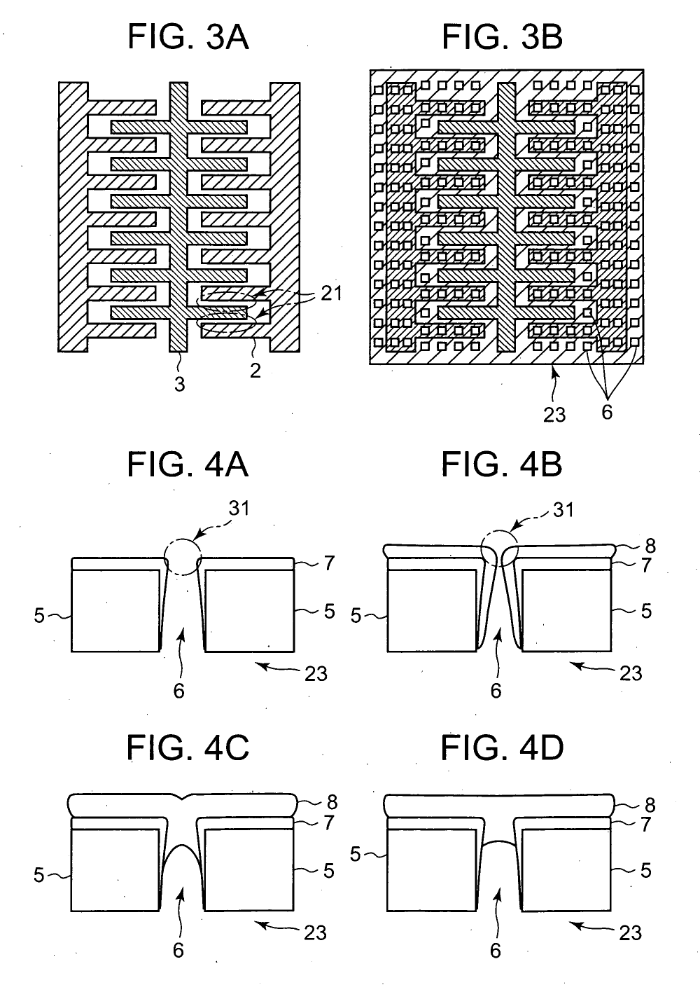

An example illustrative of the layout of the through holes 6 will now be explained based on a plan view showing the semiconductor device according to the embodiment shown in FIG. 3A and FIG. 3B.

FIG. 3A shows a layout example illustrative of electrodes 2 and a movable structural body 3. As shown in FIG. 3A, the electrodes 2 are respectively disposed on both sides of the movable structural body 3 disposed on a semiconductor substrate 1. Further, the electrodes 2 are disposed in protruded form so as to sandwich the movable structural body 3 extended in comb teeth form therebetween. Slits 21 are formed within gaps between the so-disposed movable structural body 3 extended in comb teeth form and the electrodes 2 protruded so as to sandwich the movable structural body 3 therebetween.

FIG. 3B shows a layout example illustrative of through holes 6 formed in the deposited first sealing member 5. The through holes 6 are located above a hollow region 23 (region in which the sacrifice layer 4 in FIG. 2C is left behind) corresponding to space to be sealed with vacuum. The through holes are laid out in the first sealing member 5 avoided from directly above the movable structural body 3 and the slits 21, i.e., the first sealing member 5 close to each region other than the region in which the movable structural body 3 is disposed.

Refer back to the description of FIG. 2A to FIG. 2I. After the formation of the through holes 6 in the first sealing member 5, the sacrifice film 4 is removed via the through holes 6 as shown in FIG. 2F and thereby a hollow region 23 is formed between the movable structural body 3 and the first sealing member 5. For example, the semiconductor substrate 1 is immersed in a hydrogen peroxide solution (H₂O₂) to dissolve a Ge film corresponding to the sacrifice film 4, after which it is removed. Thereafter, the semiconductor substrate 1 is fully washed and dried to form the corresponding hollow region 23.

After the removal of the sacrifice film 4, a TiN film 7 or a Ti film or a laminated film of them is deposited on the first sealing member 5 by a sputtering method as shown in FIG. 2G. The TiN film 7 is deposited to a thickness of about 100 nm, for example.

After the deposition of the TiN film 7, a second sealing member 8 (aluminum (Al)) or an aluminum (Al) alloy (hereinafter “aluminium or the like”) is further deposited or grown on the TiN film 7 by the sputtering method. Assume that the second sealing film 8 is deposited to a thickness of about 700 nm, for example.

Incidentally, the deposition of the TiN film 7 and the second sealing member 8 is as follows. For example, the TiN film 7 is grown within a vacuum chamber using a multi-chamber device or the like. Thereafter, the TiN film 7 is further conveyed to another vacuum chamber while it is being kept in its vacuum state, and the second sealing member 8 is deposited continuously.

The sputtering of the second sealing member 8 is done in the vicinity of an Argon (Ar) pressure of 2 mTorr and at temperatures between about 300° C. and about 500° C.

Further, reference numerals 22 shown in FIG. 2G indicate the TiN film 7 and the second sealing member 8 deposited within the hollow region 23 by passing through the through holes 6. However, they are not deposited on the movable structural body 3 by providing the through holes 6 such that the through holes 6 are avoided from a movable portion of the movable structural body 3 and directly above the slits 21.

Changes in the shape of each through hole 6 at the deposition of the second sealing member 8 will now be explained based on sectional views of the through hole sealed in an embodiment shown in FIG. 4A to FIG. 4D.

When a TiN film 7 is deposited on its corresponding first sealing member 5 by the sputtering method as shown in FIG. 4A, the TiN film 7 is first formed on the upper side of the first sealing member 5 and inside the through hole 6. The TiN film 7 grown on the upper side of the first sealing member 5 is deposited to an approximately uniform thickness, whereas the TiN film 7 grown inside the through hole 6 is deposited thick gradually from the hollow region 23 side of the through hole 6 to the opening 31 side. This is because the deposition of the TiN film 7 by the sputtering method increases on the opening 31 side of the through hole 6.

Next, when a second sealing member 8 is deposited by the sputtering method, the second sealing member 8 is deposited outside the TiN film 7 deposited on the upper side of the first sealing member 5 and outside the TiN film 7 deposited in the through hole 6 as shown in FIG. 4B. Since, at this time, the second sealing member 8 grows toward the center of the opening 31 in the neighborhood of the opening 31 of the through hole 6, the opening 31 gradually becomes smaller.

Further, when the second sealing member 8 is deposited while continuing sputtering, the through hole 6 is closed by the second sealing member 8 grown to the opening 31 of the through hole 6 as shown in FIG. 4C. Thus, when the second sealing member 8 constituted of aluminum or the like is grown to close the through hole 6, the aluminum or the like has flowability and flocculates owing to its own surface tension upon sputtering of aluminum or the like, which is done at a temperature range of 300° C. to 500° C. Therefore, aluminum or the like deposited inside the through hole 6 when the through hole 6 is closed, is sucked up, thereby making it possible to seal the through hole 6.

When the through hole 6 is sealed, aluminum or the like deposited inside the through hole 6 is further sucked up and the opposite surface of the hollow region 23 becomes flat, as shown in FIG. 4D.

Refer back to the description of FIG. 2A to FIG. 2I. When the second sealing member 8 is deposited on the TiN film 7, an unnecessary portion of the second sealing member 8 is removed by photolithography and etching as shown in FIG. 2H.

Since stress might occur due to a high thermal expansion coefficient of aluminum or the like and a change in temperature or the like where the second sealing member 8 is formed as aluminum or the like here, it is desirable to leave only aluminum or the like located above the through holes 6 and their outer peripheral portions and keep the influence of stress by a metal film to a minimum as shown in FIG. 2H where a region to be sealed is wide over a few tens of μm.

After the removal of the unnecessary portion of the second sealing member 8, a silicon nitride film 9 is deposited on the second sealing member 8 by the plasma CVD method or the like as shown in FIG. 2I to complete sealing. This is because since the silicon oxide film of the first sealing member has moisture-absorption characteristics, vacuum can be maintained more reliably by forming the silicon nitride film 9.

The hollow region 23 sealed with vacuum in this way can be set to not greater than 2 mTorr corresponding to Ar partial pressure during sputter. When, for example, aluminum or the like is sputtered at 400° C. and cooled to the room temperature, the degree of vacuum in the hollow region 23 can be set to 0.9 mTorr.

When the TiN film 7 and the second sealing member 8 are deposited by the sputtering method, some of the TiN film 7 or the like pass through the through holes 6 and are deposited on the semiconductor substrate 1. Since, however, the through holes 6 are not formed above the movable structural body 3 and the slits 21, the TiN film 7 and the like are not adhered to the movable structural body 3, and no influence is exerted on the operation of the movable structural body 3.

Incidentally, although the sacrifice film 4 has been explained as germanium in the present embodiment, it may be constituted as tungsten. When the sacrifice film 4 is used as tungsten, it can be removed with a hydrogen peroxide solution in a manner similar to the present embodiment.

The sacrifice film 4 can also be constituted as a silicon oxide film. In such a case, a silicon nitride film, a polysilicon film, a silicon germanium film or the like is used for the first sealing member 5. Further, the silicon oxide film may be removed with hydrofluoric acid.

Constructing the first sealing member 5 as a laminated structure of the silicon oxide film (below)/silicon nitride film (above) makes it possible to maintain vacuum reliably and sufficiently ensure adhesion to Ti or the TiN film 7 as well.

As described above, the present embodiment can bring about advantageous effects in that since the sealing member of aluminum or the like is deposited by the sputtering method to block and seal the through holes, the structural body to be sealed is not subjected to a high temperature, and the structural body formed of the material low in melting point can hence be used.

Advantageous effects are obtained in that since the sealing member of aluminum or the like is deposited by the sputtering method, the sealed hollow region can be brought into high vacuum and its high vacuum state can be held over a long period, thereby making it possible to avoid a variation in the characteristic of the structural body.

Further, advantageous effects are obtained in that since the sealing member is deposited by the sputtering method and the through holes are not formed directly above the structural body, no sealing member is deposited on the structural body and the characteristic of the structural body is prevented from varying.

Furthermore, a further advantageous effect is obtained in that since the metal material like Ti or Al serves so as to get oxygen, moisture and the like, satisfactory vacuum can be maintained even though a getter material or the like is not encapsulated.

While the preferred forms of the present invention have been described, it is to be understood that modifications will be apparent to those skilled in the art without departing from the spirit of the invention. The scope of the invention is to be determined solely by the following claims.

What is claimed is:

1. A semiconductor device manufacturing method comprising the steps of:
covering a movable structural body formed over a semiconductor substrate with a sacrifice film;
covering the sacrifice film with a first sealing member;
forming through holes in the first sealing member;
removing the sacrifice film through the through holes and forming space between the structural body and the first sealing member; and
depositing a second sealing member high in flowability over the first sealing member by a sputtering method thereby to seal the through holes.

2. The semiconductor device manufacturing method according to claim 1, wherein the through holes are disposed in the first sealing member close to regions other than a region in which the movable structural body is disposed.

3. The semiconductor device manufacturing method according to claim 1, wherein the through holes are disposed above electrodes disposed adjacent to the movable structural body.

4. The semiconductor device manufacturing method according to claim 1, wherein the through holes are undisposed above the movable structural body.

5. The semiconductor device manufacturing method according to claims 1, wherein the first sealing member is constituted as a silicon oxide film, a silicon nitride film or a laminated film thereof.

6. The semiconductor device manufacturing method according to claims 1, wherein the second sealing, member is constituted as aluminum or an aluminum alloy.

7. The semiconductor device manufacturing method according to claim 6, wherein the deposition of aluminum or the aluminum alloy by the sputtering method is done in a range of 300° C. to 500° C.
